(19) United States
(12) Patent Application Publication
(10) Pub. No.: US 2014/0197423 A1
(43) Pub. Date: Jul. 17, 2014

(54) SUBSTRATE STRUCTURE FOR MANUFACTURING LIGHT EMITTING DIODE AND METHOD FOR MANUFACTURING LIGHT EMITTING DIODE

(71) Applicant: LEXTAR ELECTRONICS CORPORATION, Hsinchu (TW)

(72) Inventors: Jui-Yi Chu, Taichung City (TW); Shih-Pu Yang, Kaohsiung City (TW)

(21) Appl. No.: 13/932,675

(22) Filed: Jul. 1, 2013

(30) Foreign Application Priority Data
Jan. 16, 2013 (TW) 102101655

(51) Int. Cl. H01L 33/20

(52) U.S. Cl. CPC H01L 33/20
USPC 257/79; 438/42

(57) ABSTRACT

The invention provides a substrate structure for manufacturing a light-emitting diode and a method for manufacturing the light-emitting diode. The substrate structure comprises a substrate having a first surface and a second surface opposite to the first surface; and a plurality of grooving structure formed on the first surface of the substrate. In which, the light-emitting diode is formed on the first surface of the substrate.

### RELATED APPLICATIONS

This application claims priority to Taiwan Application Serial Number 102101655 filed Jan. 16, 2013, which is herein incorporated by reference.

### BACKGROUND

1. Technical Field

The present disclosure relates to a substrate structure used for manufacturing a light-emitting diode and more particularly, to a lift-off substrate structure used for manufacturing a light-emitting diode.

2. Description of Related Art

In a conventional manufacturing process for a light-emitting diode, a first substrate is provided, and then a light-emitting diode structure is formed on the first substrate. Afterwards, a second substrate is jointed to the light-emitting diode structure, and the light-emitting diode structure is lifted off from the first substrate. In the conventional process, it further comprises forming a buffer layer or an oxide pattern sandwiched between the first substrate and the light-emitting diode structure.

When the lift-off process is performed, an etching solution is used to remove the first substrate by way of a chemical etching process, so as to expose the surface of the light-emitting diode structure. In which, the etching solution is needed to permeate between the first substrate and the light-emitting diode structure, such that the lift-off process is accomplished. Nonetheless, in the conventional process, the interspace between the first substrate and the light-emitting diode structure is so narrow that the reactive area for etching is insufficient and the etching rate is slow. The slower etching rate makes the longer etching time, which may damage the light-emitting diode structure in the manufacturing process.

Further, the light-emitting diode structure provided by the conventional etching process has a smooth surface, which needs performing a surface roughening step to satisfy an average light-emitting efficiency. As such, an additional manufacturing step is required, and thus the cost of production is increased. To solve the problems met in the art, there is a need for an improved substrate structure for manufacturing a light-emitting diode as well as a method for manufacturing the light-emitting diode.

### SUMMARY

The present disclosure provides a substrate structure for manufacturing a light-emitting diode and a method for manufacturing the light-emitting diode, so as to solve the problems of the prior art, and an improved manufacturing method is provided.

One aspect of the present disclosure is to provide a substrate structure for manufacturing a light-emitting diode. The substrate structure comprises a substrate having a first surface and a second surface opposite to the first surface, and a plurality of notch structures forming in the first surface of the substrate. In which, the light-emitting diode is formed on the first surface of the substrate.

Another aspect of the present disclosure is to provide a method for manufacturing the light-emitting diode. The method comprises the following steps. A first substrate is provided having a first surface and a second surface opposite to the first surface. A plurality of notch structures are formed in the first surface of the substrate. A light-emitting diode structure is formed on the first surface of the substrate. A second substrate parallel to the first substrate is formed on the surface of the light-emitting diode. Then, a lift-off process is performed to separate the first substrate and the light-emitting diode structure.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A to 1C are side views of a substrate structure according to embodiments of the present disclosure;

FIG. 1D is a side view of a stacked structure according to one embodiment of the present disclosure;

FIG. 1E is a side view of a stacked structure according to one embodiment of the present disclosure;

FIG. 1F is a side view of a stacked structure according to one embodiment of the present disclosure;

FIG. 1G is a schematic view of a lift-off process according to one embodiment of the present disclosure;

FIG. 1H is a side view of a light-emitting diode according to one embodiment of the present disclosure;

FIG. 2A to 2E are cross-sectional views of a notch structure according to embodiments of the present disclosure;

FIG. 3A is a cross-sectional view of a stacked structure according to one embodiment of the present disclosure; and

FIG. 3B is a cross-sectional view of a stacked structure according to one embodiment of the present disclosure.

### DETAILED DESCRIPTION

The a substrate structure used for manufacturing a light-emitting diode and a method for manufacturing the light-emitting diode of the embodiments are discussed in detail below, but not limited the scope of the present disclosure. The same symbols or numbers are used to the same or similar portion in the drawings or the description. And the applications of the present disclosure are not limited by the following embodiments and examples, which the person in the art can apply in the related field.

The present disclosure provides a substrate structure used for manufacturing a light-emitting diode and a method for manufacturing the light-emitting diode. In which, the substrate structure comprises a plurality of notch structures, so as to increase the efficiency of a lift-off process.

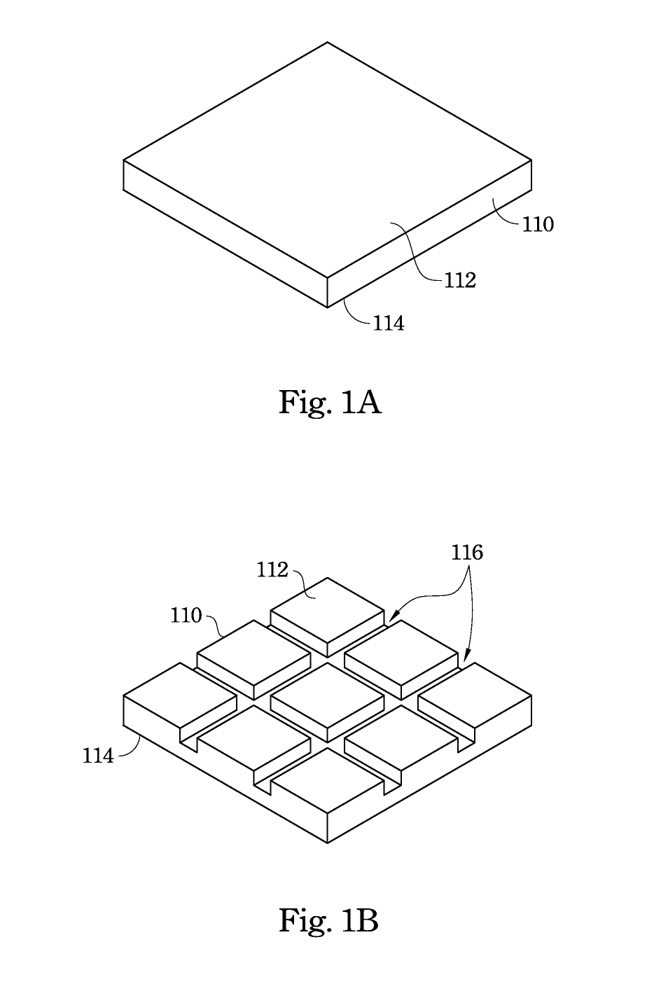

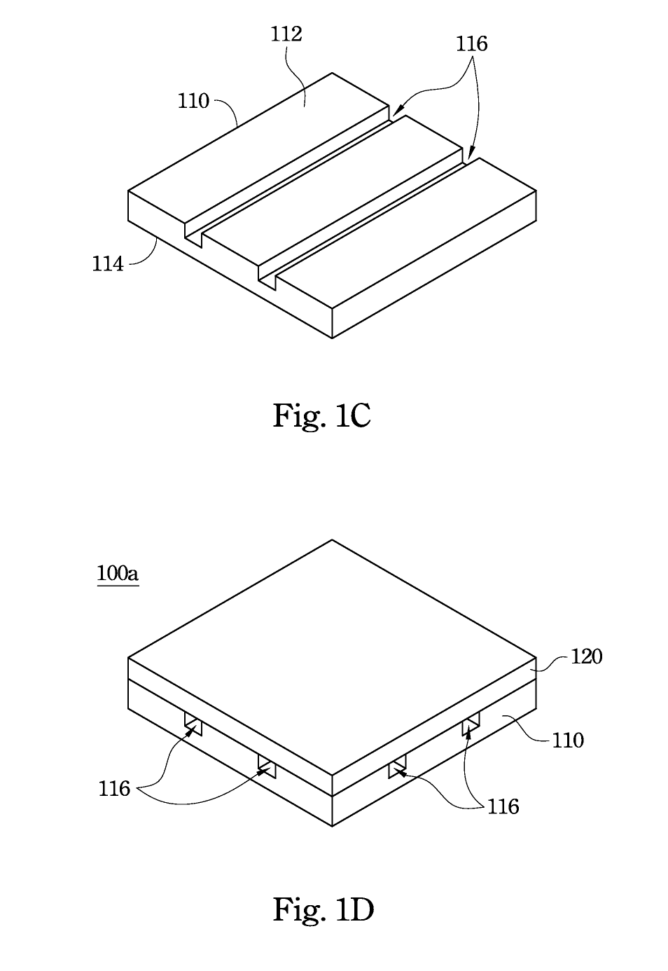

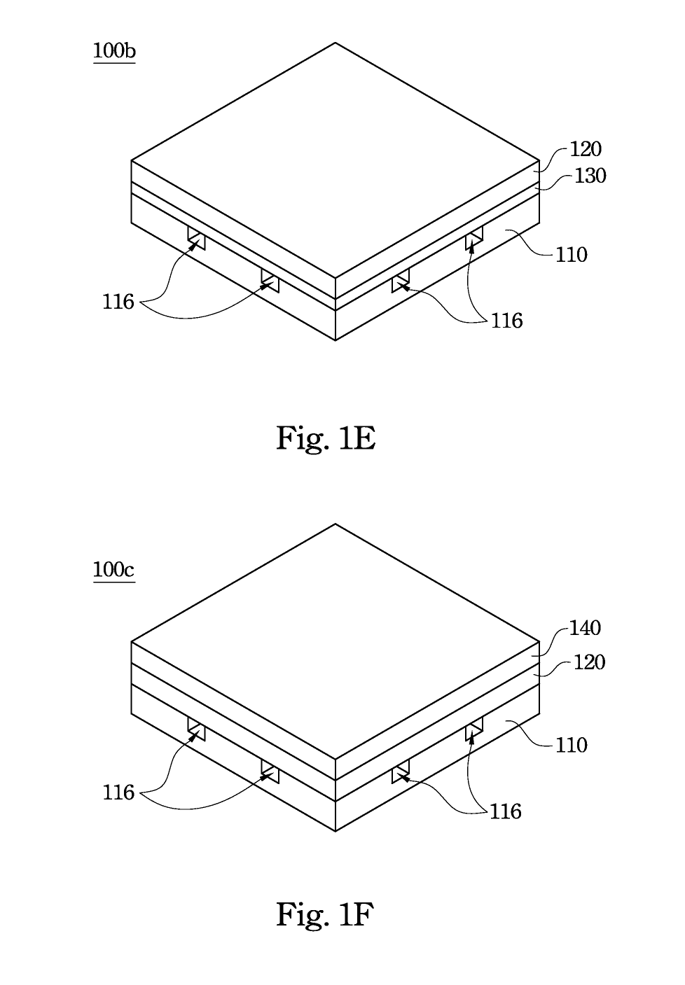

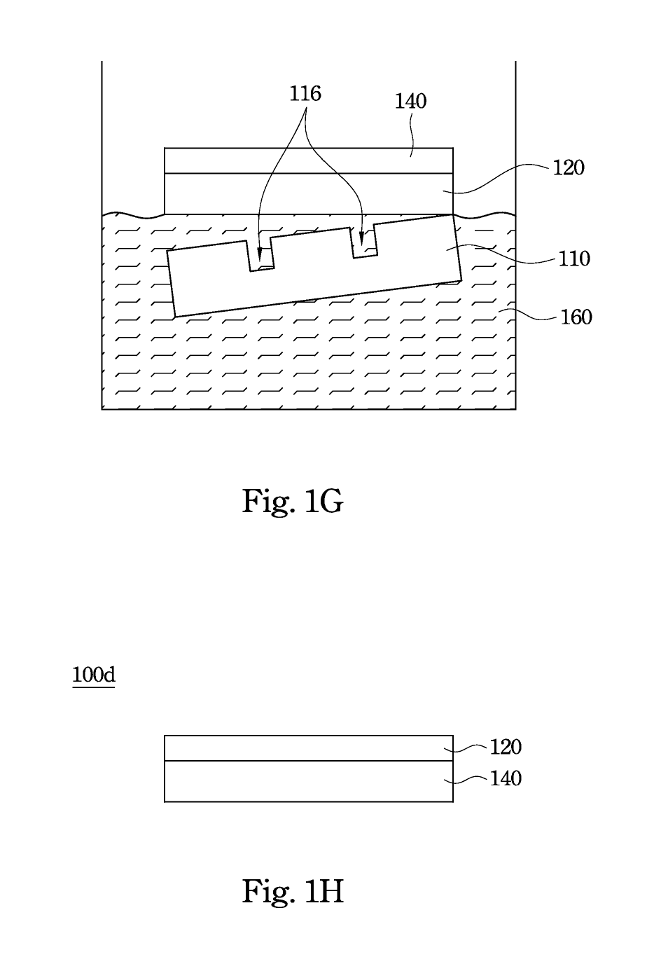

FIG. 1A to 1C are side views of a substrate structure according to embodiments of the present disclosure. In FIG. 1A, the first substrate 110 is provided, wherein the first substrate 110 has a first surface 112 and a second surface 114. According to one embodiment of the present disclosure, the material of the first substrate is selected from a group comprising of sapphire, silicon, silicon carbide (SiC), lithium aluminate (LiAlO₂), lithium gallate (LiGaO₂), zinc oxide (ZnO), gallium arsenide (GaAs), gallium phosphide (GaP), and a combination thereof.

In FIG. 1B, a plurality of notch structures 116 are formed in the first surface 112 of the first substrate 110. In which, the notch structures 116 are crisscrossed as a network. According to one embodiment of the present disclosure, the notch structures 116 are parallel as shown in FIG. 1C.

The notch structures 116 are a plurality of hollow recess structures formed by a dry etching method or a wet etching method, and are expended to the edges of the first substrate 110 to form a plurality of openings.

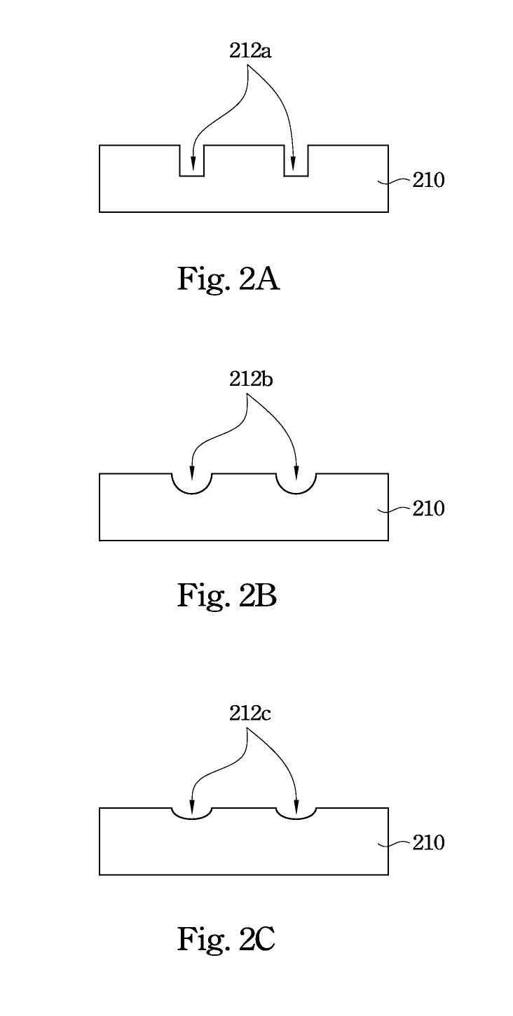

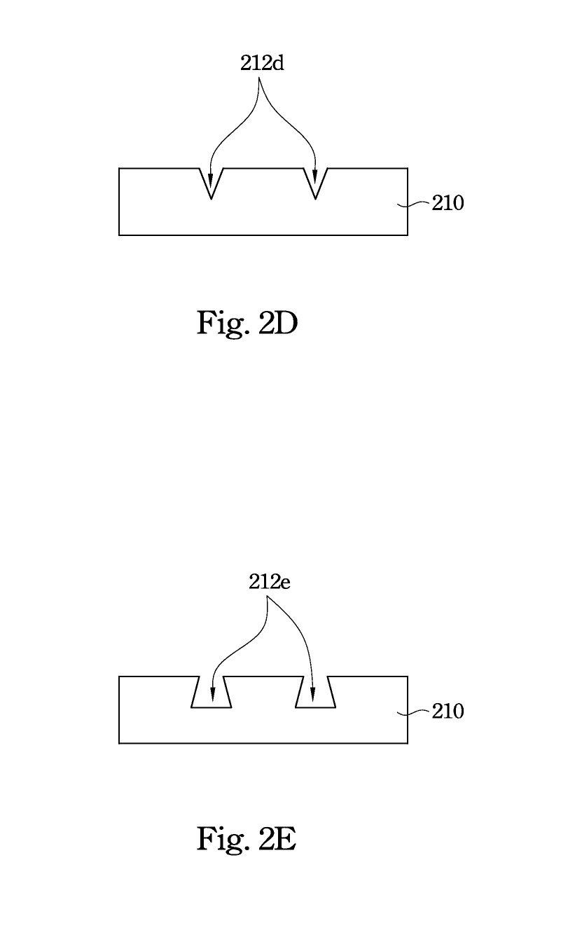

FIG. 2A to 2E are cross-sectional views of a notch structure according to embodiments of the present disclosure. In FIG. 2A to 2E, the first substrate 210 has a plurality of notch structures 212, and the cross section of the notch structures 212 is rectangle 212a, semicircle 212b, arc 212c, triangle 212d, trapezoid 212e, or a combination thereof. According to one example of the present disclosure, the depth of the notch structures 212 is in a range of 0.1 μm to 50 μm.

FIG. 1D is a side view of a stacked structure according to one embodiment of the present disclosure. Followed by FIG. 1B, a light-emitting diode structure 120 is formed on the first surface 112 of the first substrate 110. In which, the light-emitting diode structure 120 comprises an N-type semiconductor layer, a light-emitting layer, a P-type semiconductor layer and a conductive layer. The N-type semiconductor layer, the light-emitting layer the P-type semiconductor layer and the conductive layer is sequentially formed on the first surface 112 of the first substrate 110 to form a stacked structure 100a. According to one example of the present disclosure, the components of the light-emitting diode structure 120 comprise III-V semiconductor, such as gallium nitride (GaN) or indium phosphide (InP). According to one example of the present disclosure, the N-type semiconductor layer, the light-emitting semiconductor layer and the P-type semiconductor layer are formed by epitaxy methods. According to one example of the present disclosure, the conductive layer is formed by an electroplating or a deposition, and the method of the conductive layer is copper (Cu), nickel (Ni), molybdenum (Mo), aluminum (Al), or a combination thereof.

FIG. 1E is a side view of a stacked structure according to one embodiment of the present disclosure. In FIG. 1E, the stacked structure 100b further comprises a buffer layer 130 formed between the first surface 112 of the first substrate 110 and the light-emitting diode structure 120. In which, the buffer layer 130 is formed by an epitaxy method to provide the stacked structure 100b. Compared to the method of the N-type semiconductor layer in the light-emitting diode structure 120, the material of the buffer layer 130 has better etching rate, and may improve the lift-off process of the first substrate 110. However, according to one embodiment of the present disclosure, the lift-off process of the first substrate 110 is performed even the buffer layer 130 is lacked, and the light-emitting diode structure 120 may not be damaged.

According to one example of the present disclosure, the depth of the buffer layer 130 is equal to or less than 100 nm. According to another example of the present disclosure, the material of the buffer layer 130 is silicon oxide (SiOx), silicon nitride (SiNx) or chromium nitride (CrN).

FIG. 1F is a side view of a stacked structure according to one embodiment of the present disclosure. In FIG. 1F, a second substrate 140 followed by FIG. 1D is formed on the light-emitting diode structure 120 to form the stacked structure 100c. The second substrate 140 is parallel to the first substrate 110. According to one embodiment of the present disclosure, the second substrate 140 is annealed with the light-emitting diode structure 120 by pressing on the second substrate 140. According to one embodiment of the present disclosure, the second substrate 140 is a transparent substrate. According to another example of the present disclosure, the material of the second substrate 140 is selected from a group comprising of sapphire, silicon (Si), silicon carbide (SiC), lithium aluminate (LiAlO₂), lithium gallate (LiGaO₂), zinc oxide (ZnO), gallium arsenide (GaAs), gallium phosphide (GaP), and a combination thereof.

FIG. 1G is a schematic view of a lift-off process according to one embodiment of the present disclosure. In FIG. 1G, the stacked structure 110c in FIG. 100c is immersed in the etching solution 160 to isolate the first substrate 110 and the light-emitting diode structure 120, so as to explode a surface of the light-emitting structure 120. Since the etching solution 160 can flow into the first surface 112 of the first substrate 110, the reactive rate of the etching solution 160 may be increased, so as to increase the etching rate.

FIG. 1H is a side view of a light-emitting diode according to one embodiment of the present disclosure. In FIG. 1H, after the first substrate 110 in FIG. 1G is removed, the light-emitting diode structure 120 and the second structure 140 are reversed 180 degrees to provide the light-emitting diode 100d, wherein the light-emitting diode 120 is positioned on the second substrate 140. According to one embodiment of the present disclosure, after the lift-off process, the exploded surface of the light-emitting diode 120 is rough, which may increase the light-emitting efficiency of the light-emitting diode 100d.

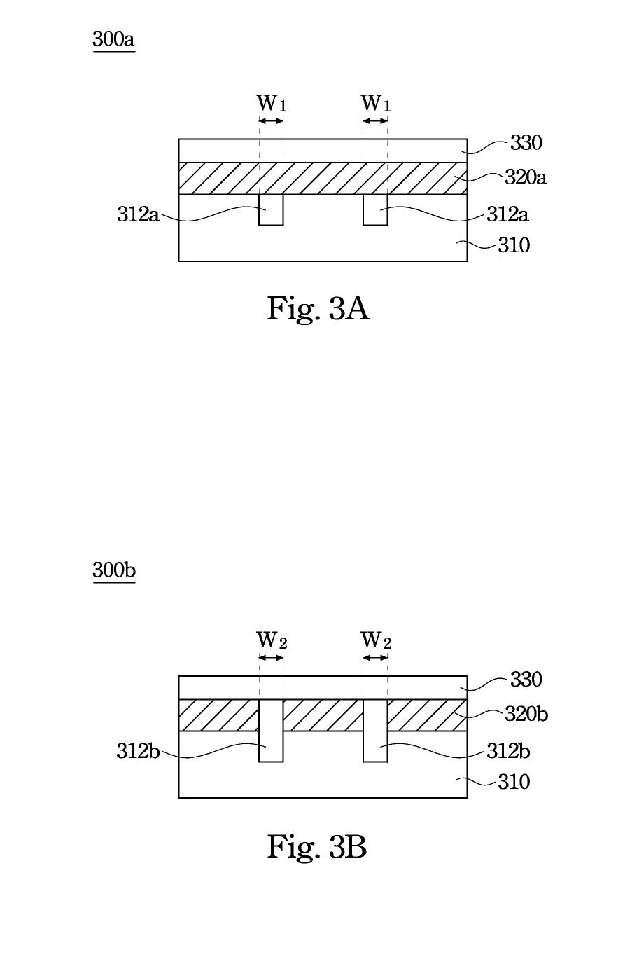

FIG. 3A is a cross-sectional view of a stacked structure according to one embodiment of the present disclosure. In FIG. 3A, the stacked structure 300a includes a first substrate 310, a light-emitting diode structure 320a and a second substrate 330. The first substrate 310 has a plurality of notch structures 312a, wherein the opening width (W₁) of the notch structure 312a is less than 10 μm. It is noteworthy that, when the opening width (W₁) of the notch structure 312a is less than 10 μm, the light-emitting diode structure 320a may be performed lateral epitaxy on the notch structure 312a to form a continuous light-emitting diode structure 320a. And the second substrate 330 is formed on the light-emitting diode structure 320a to provide the stacked light-emitting diode structure 300a.

FIG. 3B is a cross-sectional view of a stacked structure according to one embodiment of the present disclosure. In FIG. 3B, the stacked structure 300b includes a first substrate 310, a light-emitting diode structure 320b and a second structure 330. The first substrate 310 has a plurality of notch structures 312b, wherein the opening width (W₂) of the notch structure 312b is larger than 10 μm. It is noteworthy that, when the opening width (W₂) of the notch structure 312a is large than 10 μm, the light-emitting diode structure 320a cannot be performed lateral epitaxy on the notch structure 312a, and is formed a discontinuous light-emitting diode structure 320b. And the second substrate 330 is formed on the light-emitting diode structure 320b to provide the stacked light-emitting diode structure 300b.

In embodiments of the present disclosure, the etching solution flows into the notch structures formed on the first substrate, which may increase the reactive area for etching, and increase the etching rate to prevent the damage of the light-emitting diode structure. Therefore, the method for manufacturing the light-emitting diode provided by the present disclosure may solve the problems met in the art.

On the other hand, after the lift-off process, the first substrate and the light-emitting diode structure are isolated, and the rough surface of the light-emitting diode is exploded. Therefore, there is no need an extra surface roughening step to improve the light-emitting efficiency of the light-emitting diode. Known as the above, the method for manufacturing the light-emitting diode provided by the present disclosure may simplify the process for manufacturing a light-emitting diode to decrease the producing cost.

Although embodiments of the present disclosure and their advantages have been described in detail, they are not used to limit the present disclosure. It should be understood that various changes, substitutions and alterations can be made herein without departing from the spirit and scope of the present disclosure. Therefore, the protecting scope of the present disclosure should be defined as the following claims.

What is claimed is:

1. A substrate structure for manufacturing a light-emitting diode, comprising:
a substrate having a first surface and a second surface opposite to the first surface; and
a plurality of notch structures formed on the first surface of the substrate,
wherein the light-emitting diode is formed on the first surface of the substrate.

2. The substrate structure of claim 1, wherein the notch structures expand to the edges of the substrate to form a plurality of openings.

3. The substrate structure of claim 1, wherein the notch structures are parallel with each other, or crisscrossed as a network.

4. The substrate structure of claim 1, wherein the cross section of the notch structures is rectangle, semicircle, arc, triangle, trapezoid, or a combination thereof.

5. The substrate structure of claim 1, wherein the depth of the notch structure is in a range of 0.1 μm to 50 μm.

6. The substrate structure of claim 1, wherein the material of the substrate is selected from the group consisting of sapphire, silicon, silicon carbide (SiC), lithium aluminate (LiAlO₂), lithium gallate (LiGaO₂), zinc oxide (ZnO), gallium arsenide (GaAs), gallium phosphide (GaP), and a combination thereof.

7. A method for manufacturing a light-emitting diode, comprising the steps of:
providing a first substrate having a first surface and a second surface opposite to the first surface;
forming a plurality of notch structures in the first surface of the first substrate;
forming a light-emitting diode structure on the first surface of the first substrate;
forming a second substrate parallel to the first substrate on the surface of the light-emitting diode structure; and
performing a lift-off process to separate the first substrate and the light-emitting diode structure.

8. The method of claim 7, wherein the step of forming the light-emitting diode structure comprises:
forming an N-type semiconductor layer on the first substrate;
forming a light-emitting layer on the N-type semiconductor layer;
forming a P-type semiconductor layer on the light-emitting layer; and
forming a conductive layer on the P-type semiconductor layer.

9. The method of claim 7, further comprising the step of forming a buffer layer between the first surface of the first substrate and the light-emitting diode structure.

10. The method of claim 9, wherein the N-type semiconductor layer, the light-emitting layer, the P-type semiconductor layer and the buffer layer are formed by an epitaxy process.

11. The method of claim 9, wherein the thickness of the buffer layer is equal to and less than 100 nm.

12. The method of claim 7, wherein the notch structures are formed by a dry etching process or a wet etching process.

13. The method of claim 7, wherein the notch structures expand to the edge of the first substrate to form a plurality of openings.

14. The method of claim 7, wherein the notch structures are parallel with each other, or crisscrossed as a network.

15. The method of claim 7, wherein the cross section of the notch structures is rectangle, semicircle, arc, triangle, trapezoid, or a combination thereof.

16. The method of claim 7, wherein the depth of the notch structure is in a range of 0.1 μm to 50 μm.

17. The method of claim 7, wherein the material of the substrate is selected from the group consisting of sapphire, silicon, silicon carbide (SiC), lithium aluminate (LiAlO₂), lithium gallate (LiGaO₂), zinc oxide (ZnO), gallium arsenide (GaAs), gallium phosphide (GaP), and a combination thereof.

18. The method of claim 7, wherein the lift-off process is performed by a wet etching process.
